(19) United States
(12) Patent Application Publication
(10) Pub. No.: US 2016/0057859 A1
(43) Pub. Date: Feb. 25, 2016

(54) ELECTRON SPIN FILTER

(71) Applicants: Juan José de Miguel, Madrid (ES); Francisco Jesús Luque, Madrid (ES); Miguel Ángel Niño, Madrid (ES); Rodolfo Miranda, Madrid (ES); Iwona Agniezska Kowalik, Skierniewice (PL); Dimitri Arvantis, Uppsala (SE)

(72) Inventors: Juan José de Miguel, Madrid (ES); Francisco Jesús Luque, Madrid (ES); Miguel Ángel Niño, Madrid (ES); Rodolfo Miranda, Madrid (ES); Iwona Agniezska Kowalik, Skierniewice (PL); Dimitri Arvantis, Uppsala (SE)

(21) Appl. No.: 14/830,239

(22) Filed: Aug. 19, 2015

Related U.S. Application Data
(60) Provisional application No. 62/040,038, filed on Aug. 21, 2014.

(51) Int. Cl. H05K 1/11; H05K 1/03

(52) U.S. Cl. CPC H05K 1/11; H05K 1/03; H05K 2201/10227

(57) ABSTRACT

The present invention relates to a device and a method for the control of the orientation of electron spins and spin currents. According to the invention an electron spin filter device is provided with a first and a second electrode with a chiral layer arranged there between. The chiral layer comprises at least one type of chiral molecules that is intrinsically chiral and the chiral molecules are disorderly distributed on the first conducting layer with a predefined preferential orientation and without long-range periodicity. By using different enantiomers it is possible to control the direction of the spin polarisation of electrons excited by means of incoming radition.

### FIELD OF THE INVENTION

The present invention relates to a device and a method for the control of the orientation of electron spins and spin currents. In particular the invention relates to a device and a method based on the use of chiral molecules.

### STATE OF THE ART

Spintronics has been one of the most promising and fastest growing fields of research in solid state physics and materials science during the last years. The main goal of research in this area is to develop methods and devices allowing the use of the electron spin rather than its electric charge as the carrier of information in electronic devices. The main advantages of this approach are the longer coherence length and smaller probability of scattering of the electron spins during their transport, which should result in higher carrier velocities and lower energy consumption. A successful implementation of this novel technology would allow for significant reductions in the emissions of greenhouse gases associated to the operation of computing and telecommunications equipment and also in a considerable improvement of the performance of portable devices.

One of the main problems that need to be solved for a successful development of spintronics as a mature and viable technology is the efficient obtention and detection of spins. Traditionally, spin-polarised electron currents have been produced by optical excitation of semiconducting (e.g., GaAs) photocathodes with circularly polarised light. This method remains today the choice for research applications because high polarisations can be achieved: up to 92% is reported but at the cost of a very low efficiency (about 0.5%) and for very weak intensities. If needed, stronger currents can be attained at the expense of lower polarisation: current state-of-the-art commercial instruments quote 1 μA at 27% spin polarisation. This procedure is thus rather inefficient and difficult to integrate in miniaturised spintronic devices. Another approach to obtain spin-polarised currents involves the use of half-metals such as magnetite (Fe₃O₄) or CrO₂ that can in principle present nearly 100% spin polarisation, but the preparation of homogeneous thin films of these materials with good structural quality and the correct stoichiometry has proven problematic. Finally, another very broad field of research is centred on the so-called diluted magnetic semiconductors, which could allow for a direct integration of spintronic devices with the more traditional semiconductor technology, but the introduction of the magnetic impurities in concentrations of the order of 4-8% at random positions within the host crystal lattice and avoiding clustering is extremely difficult and the operation conditions (Curie temperature) of these materials are typically well below room temperature.

Spin-sensitive detection suffers from similar limitations. Traditional Mott detectors are based on the inherently weak effect of spin-orbit coupling (SOC) and typically derive the magnitude of spin polarisation from the asymmetry in the scattering of electrons at the surface of some heavy element such as tungsten (W) or gold (Au). This type of set-up requires high accelerating voltages (around 30-40 keV at least) to achieve efficiencies only of the order of 10⁻⁴. Other detection schemes are based on the use of spin filters; the first realisations of this type of devices made use of the Giant Magneto-Resistance effect in multilayers of magnetic transition metals but nowadays the focus for spin filtering has shifted to magnetic tunnelling junctions, which are expected to be much more efficient because the tunnelling process is basically elastic and the spin orientation should be conserved. The main difficulty in this case is the preparation of insulating tunnelling barriers of high enough structural quality and homogeneity. All the methods outlined above share a common characteristic: the spin selectivity is based on making use of the spin-orbit coupling interaction, a magnitude that is intrinsically very weak and that scales with the atomic mass. Hence, to obtain a significant spin separation it is necessary to employ heavy atoms, which in turn results in high spin scattering probabilities and short coherence lengths. The information encoded in the electron spin would then be quickly lost.

A radically new approach has appeared recently: the basic idea is to use the chiral symmetry possessed by certain types of organic molecules to reorient the spin of electrons transmitted across them. Since these molecules only contain light atoms, their spin-orbit coupling is negligible and the spin coherence length can be extremely long. The origin of the spin polarisation seems to be related to the effective magnetic field that appears within the molecules due to the helical symmetry of their inner potential. A pioneering work, presented in B. Gohler et al., Science 331, 894 (2011), along this line has demonstrated that spin polarisation as high as 60% can be obtained using chiral chains of double-stranded DNA arranged on a metallic (Au) substrate. The procedure to achieve spin polarisation based on the results of this study is the subject of a European Patent Application number EP 2 492 984. The published work and EP 2 492 984 are based on a comparison of the results of the spin polarisation measured on two systems, namely single- and double-stranded DNA chains, with a single helicity. The former molecules form disordered layers whereas the latter ones display a high degree of spatial order.

From these experimental data it is concluded that the ordered arrangement of the chiral molecules on the solid substrate is an essential requirement for the achievement of spin polarisation. This restriction seriously limits the applicability of this technique for practical purposes, since the number of combinations substrate/molecule satisfying that requirement might be very small, and the preparation conditions needed to obtain stable, well-ordered arrangement of the molecules are difficult and costly to determine Furthermore, although the experiments were carried out with molecules with a single helicity, it is assumed without demonstration that the sign of the spin polarisation will be reversed by using the opposite enantiomer. If this were the case, this fact would also represent a limitation for the possible combination of these spin-filtering molecular films with other spin-polarized materials such as ferromagnetic metals.

### SUMMARY OF THE INVENTION

The above described work represents significant improvements in order to provide electron spin filters and devices utilizing such, for example spin sensitive detection devices. However, the described devices will be very costly to produce and sensitive and prone to degeneration during use.

The object of the invention is to provide a device that overcomes the drawbacks of prior art techniques. This is achieved by the spin filter as defined in claim 1.

The spin filter according to the invention comprises a first and a second electrode with a chiral layer arranged there between. The chiral layer comprises at least one type of chiral molecules that is intrinsically chiral and the chiral molecules are disorderly distributed on the first conducting layer with a predefined preferential orientation but no long-range periodicity.

By using different enantiomers it is possible to control the direction of the spin polarisation of electrons excited by means of incoming radition.

According to one embodiment the spin filter device further comprises an insulating material forming an insulating protecting layer. The insulating protective layer may be formed of a metal oxide such as Al2O3, MgO or SiO2.

According to another embodiment the chiral layer comprises a nanoparticle layer of disordered close packed metallic nanoparticles and the chiral molecules are chemisorbed on the nano particles.

According to one embodiment the chiral layer comprises 1,2-diphenyl-1,2-ethanediol. The chiral layer may comprises chiral molecules of different enantiomers.

According to a further embodiment the spin filter forms the basis of a spin switch device comprising an insulating substrate embedding a series of parallel conducting lines, a ferromagnetic film arranged on top of the insulating layer, a chiral layer comprising chiral molecules arranged on top of the ferromagnetic film and a metallic layer arranged on the chiral layer.

One advantage of the present invention is that chiral molecules of low complexity can be used simplifying the design and lowering production cost.

A further advantage is that no long-range periodical arrangement of the molecules on the supporting substrate is required to achieve a significant spin filtering effect, substantially reducing the degree of control needed during the fabrication.

A yet further advantage is that specific guidelines are provided regarding the orientation that the molecules must adopt on the supporting substrate in order to produce the spin polarization along a particular direction of interest.

A further advantage is that the electron spin filter is less sensitive to the surrounding environment compared to prior art devices.

A further advantage is the possibility to select the angle of rotation of the spin provoked by the molecular layer. This can be utilized to fabricate spin-sensitive switches, by depositing the film of chiral molecules on top of a ferromagnetic layer whose magnetization direction can be controlled by means of an externally applied magnetic film.

### BRIEF DESCRIPTION OF THE FIGURES

FIG. 1 a-b: A schematic illustration of the electron spin filter device according to the invention (a) and its operation (b);

FIG. 2 a-b: The two chiral forms or enantiomers denoted (R,R)-(+)-DPED and (S,S)-(−)-DPED respectively, utilized in one embodiment of the invention;

FIG. 3 a-b: A schematic illustration of one embodiment of the electron spin filter device according to the invention utilizing a nanocomposite (a) and (b) illustrates the device with a protective layer;

FIG. 4 a-c: A schematic illustration of one embodiment of the electron spin filter device according to the invention forming a spin switch device (a) and its operation (b) and (c);

FIG. 5 a-b: LEED patterns measured at 300 K with a primary beam energy of 133 eV for (a) a bare 8 ML Co film epitaxially grown on Cu(100), and (b) the same sample after adsorbing a monolayer-thick film of (S,S)-DPED molecules;

FIG. 6 a-c: Angular dependence of the XAS intensity measured in a (S,S)-DPED layer adsorbed on Co/Cu(100). The intensities are directly proportional to the transition probabilities into different final states: (a) a π* molecular orbital which is perpendicular to the two phenyl rings of the DPED molecule, and (b) the σ* orbitals that run longitudinally between each pair of C atoms. The condition of these two types of transitions being maximum for nearly normal incidence of the x ray beam implies an arrangement of the molecules on the surface as schematically shown in (c);

FIG. 7 a-c: Angular dependence of the XAS intensity measured in a (R,R)-DPED film adsorbed on Co/Cu(100). In this case the transition probability into the π* orbitals is maximum for grazing x ray beam incidence, from which a molecular adsorption geometry such as the one depicted in (c) can be deduced;

FIG. 8 a-b: In-plane (a) and out-of-plane (b) spin polarization spectra measured at k∥=0 and 300 K. The sample was magnetized parallel to the surface, and the in-plane spin polarization of the Co d-electrons can be clearly observed below the Fermi energy;

FIG. 9 a-b: In-plane (a) and out-of plane (b) spin polarization spectra measured at k∥=0 and 300 K, with the sample magnetized in-plane. An approximately energy-independent, in-plane spin polarization can be observed in the photoemitted electrons;

FIG. 10 a-b: In-plane (a) and out-of plane (b) spin polarization spectra at k∥=0 and 300 K. In spite of having the sample magnetized in-plane as in the previous experiment with (R,R)-(+)-DPED, the photoemitted electrons are spin-polarized out-of-plane in this case, with a magnitude also independent of their binding energy; the Co d-electrons maintain their in-plane polarization though.

### DETAILED DESCRIPTION OF THE INVENTION

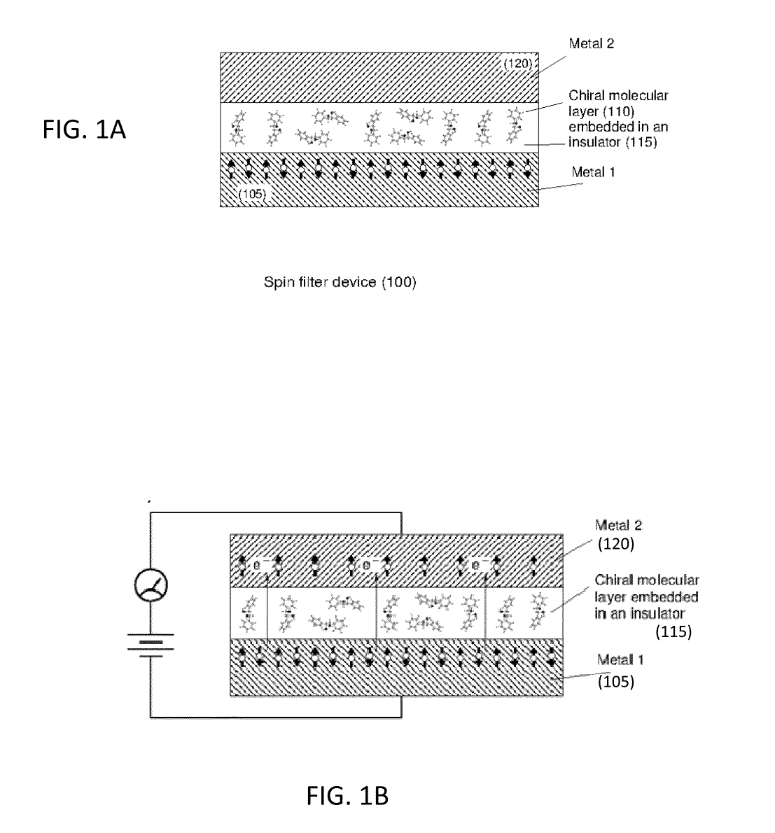

The electron spin filter device 100 according to the invention is shown schematically in FIG. 1a. The electron spin filter device 100 comprises a conducting substrate 105 that can be metallic or semiconducting with an appropriate level of doping. On top of this conducting substrate 105, which serves as the first electrode in the device, a layer of molecules with chiral symmetry, referred to as the chiral layer 110 is provided. According to the present invention the molecules are intrinsically chiral and have an average spatial orientation appropriate to define the spin polarization along the desired direction; the adsorbed molecules should not have a well-defined periodic arrangement in the surface plane. These properties will be further discussed below.

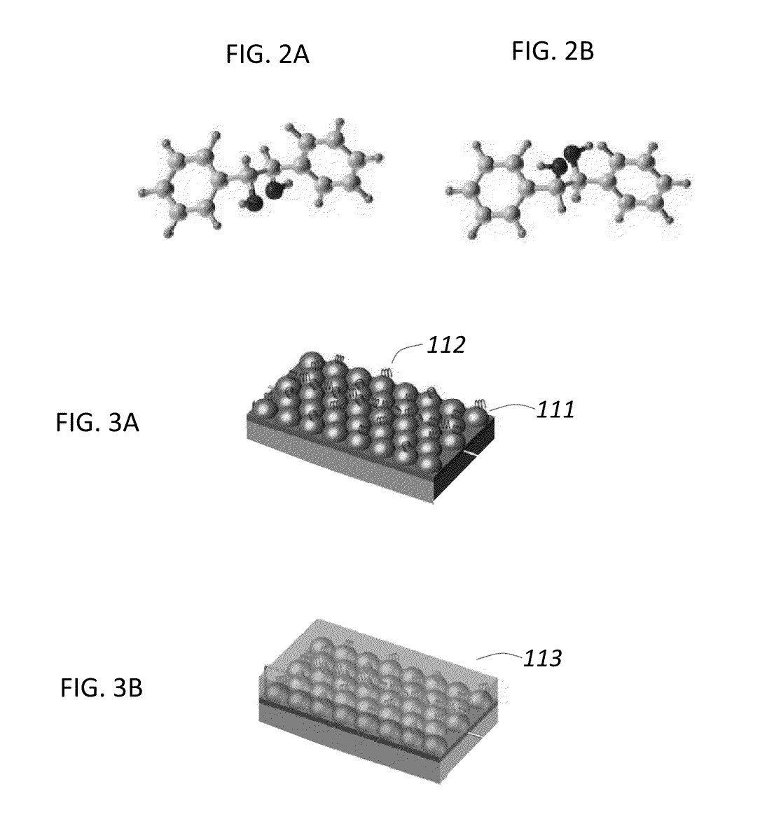

Methods of providing the layer of molecules 110 with chiral symmetry includes, but is not limited to, evaporation in vacuum or deposition in liquid solution. Examples of chiral molecules include, but is not limited to 1,2-diphenyl-1,2-ethanediol (DPED). This compound presents two chiral forms or enantiomers denoted (R,R)-(+)-DPED and (S,S)-(−)-DPED respectively, and schematically illustrated in FIG. 2a-b. These molecules should be electrically conducting, for example mainly through extended π molecular orbitals, and should preferably be enantiomerically pure, that is, they should possess a single helical symmetry or handedness. The chiral molecules should not have the form of helicoidal long chains; they should preferably have relatively small sizes (not larger than 2-3 nm) and rigid conformations so that they can form a stable arrangement with well defined orientation when adsorbed on the surface. In order to be able to transmit the maximum electrical current density the molecular film 110 should be as dense as possible, with an atomic density preferably above 1×10²² atoms/cm³, and even more preferably above 1×10²³ atoms/cm³. The optimum thickness of this molecular layer to obtain the maximum spin polarization should be between 20 and 30 nm but thinner films can also be used for specific purposes; in any case, not larger than the estimated typical spin coherence length in organic materials, which is of the order of 60-80 nm. Optionally, for chemical and mechanical protection and increased stability the molecules can be embedded within an insulating material forming an insulating protecting layer 115, such as Al₂O₃, MgO, SiO₂ or other similar materials, in such a way that the electrical conduction takes place through the embedded chiral molecules. A second conducting electrode 120 is placed on top of the molecular and passivating layer. This layer can be made of a metallic, semiconducting or conducting organic material, and its thickness can be adjusted depending on the application desired, ranging from about 5 nm to macroscopic dimensions.

The principle of operation of this device 100 is schematically depicted in FIG. 1b. A voltage difference created by power supply 125 can be applied to the two electrodes 105 and 120 by means of electrical connections 130 thereby establishing a current of electrons flowing from one electrode to the other across the chiral layer 110. If for instance the first electrode 105 is biased negative with respect to the second electrode 120, the current of electrons will flow from 105 towards 120. Although the population of both spin components is the same in the first electrode 105, the chiral molecular layer 110 blocks the passage of one of them thus allowing to inject a spin-polarized electron current into the second electrode 120. If this second electrode is made up of a semiconductor material, it could constitute the source of a MOSFET type spin-based transistor. Alternatively, if electrode 105 is biased positive with respect to electrode 120 then the device can operate as a spin detector: a current of spin-polarized electrons incident upon electrode 120 will be selectively transmitted across the molecular layer 110 according to their spin, resulting in either a high or a low transmitted current.

According to one embodiment of the invention the chiral layer 110 is realized as a disordered nanocomposite, which incorporates and exploits the chiral molecules adsorbed with a preferential orientation onto the surface of metallic nanoparticles randomly distributed in a layer arrangement. The chiral layer 110 comprises a nanoparticle layer 111 of disordered close packed metallic nanoparticles and chemisorbed chiral molecules 112, forming the nanocomposite as illustrated in FIG. 3a. This geometry exploits the high surface to volume ratio of the nanoparticles for embedding a high number of chiral molecules within the conducting layer by means of chemisorption. The chiral molecules preferably are to cover the surface of conductive nanoparticles, which form a disordered assembly in close contact, close to the nanocomposite's electric conductivity percolation threshold. Being close to the percolation threshold for the electric conductivity, allows to maximize spin dependent effects in electric conductivity measurements. The close nanoparticle proximity allows for electric conductivity through electron hoping or electron tunneling from particle to particle, leading to an increased spin polarization for each electron hoping, as for each hoping the electrons have to cross the chiral molecular layer covering the nanoparticles. It is possible to use a nanoparticle close packed array beyond the percolation threshold, however this will decrease the spin contrast of the device. Preferably the nanoparticles have an average size across in the order of a fraction of a micron in size (of order 0.5 micron). Preferably the nanoparticle layer 111 comprises nanoparticles with good electrical conductivity characteristics and capable to bind strongly the chiral molecular layer. This latter effect can be accomplished with transition metals such as Fe, Co, Ni, Pd or Pt. Alternatively, noble metals such as Cu, Ag or Au offer better conductivity and higher chemical stability. Strong binding to this metallic nanoparticles can be achieved using chiral molecules containing N or S atoms, such as for instance thiol-terminated compounds. This procedure can have significant practical advantages, because the methods for the preparation of Au nanoparticles and their decoration with organic molecules have been investigated in depth and are well developed; furthermore, given their chemical inertness, their deposition onto the first conducting electrode 105 could be carried out under atmospheric conditions or even in liquid solution. Also combination of nanoparticles of different metals and/or alloys could be used.

FIG. 3b schematically illustrates the nanoparticle composite described with reference to FIG. 3a embedded in a protective layer 310, for example, but not limited to, a layer of resin that provides both mechanical and chemical protection without affecting the filtering properties. The protective layer 310 should be arranged so that conductive pathways between the first electrode 105 is biased and the second electrode 120 are maintained.

Various preparation procedures for the device according to this embodiment of the invention utilizing nanoparticles can be envisioned depending on the dimensionality of the geometry to be used, for assembling a spin filter device such as shown. For an open surface geometry first the nanoparticle assembly can be brought on the surface and subsequently the chiral molecules evaporated on the surface. We present direct evidence of this type of preparation with DPED molecules and a metallic Co surface at room temperature. Alternatively, the metallic nanoparticles can be synthesized and coated with the chiral molecules for instance by chemical methods in solution and then the nanocomposite conductive layer, FIG. 3a or three dimensional nanocomposite formed, FIG. 3b, by deposition onto the corresponding substrate.

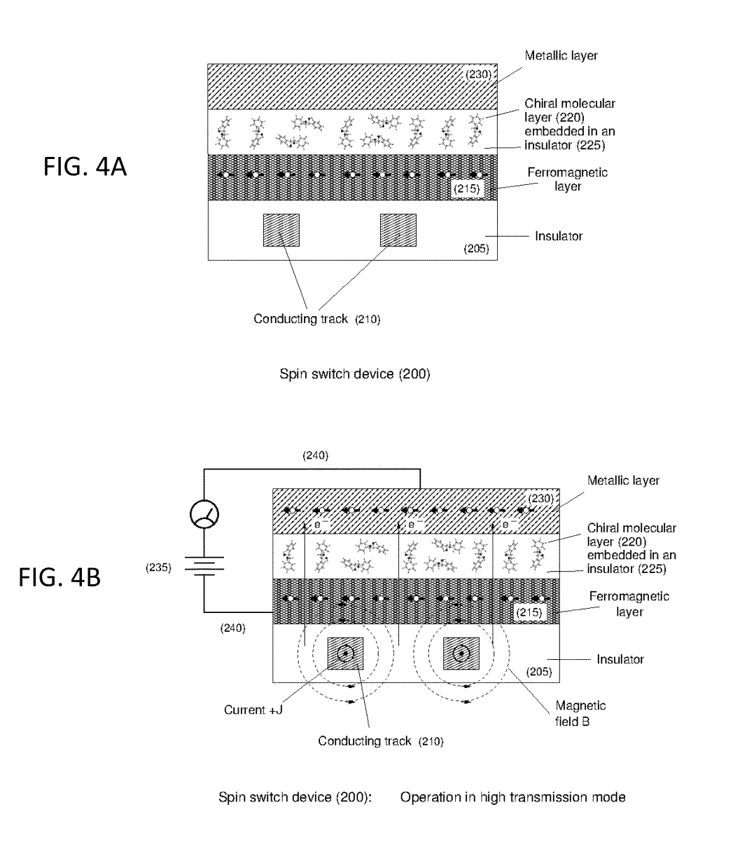

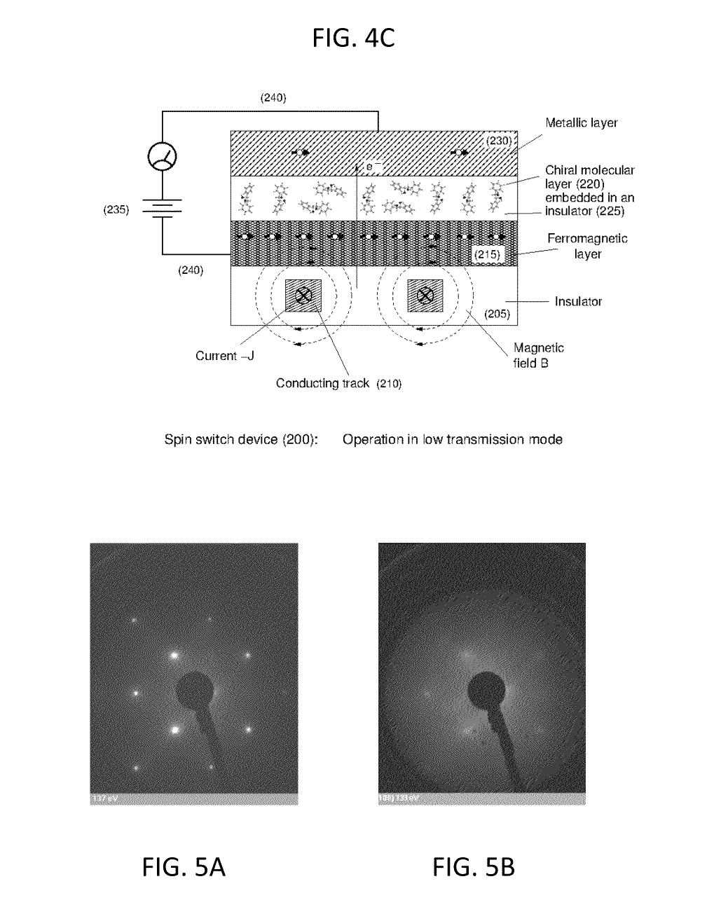

In a further embodiment the device according to the invention is used to form an electron spin switch device 200 shown schematically in FIG. 4a. This device comprises an insulating substrate 205 that can be made up of materials such as SiO₂ or Al₂O₃ or MgO embedding a series of parallel conducting lines 210 made up of a metallic material such as Cu, Al, Au or similar. These conducting lines can have a transverse section of different shapes: circular, square or any other. They can be embedded within the insulating substrate preferably by microlithography techniques. On top of this insulating layer 205 a ferromagnetic film 215 is arranged comprising a ferromagnetic material such as Co, Fe, Permalloy (Py) or other compounds including these former is placed. This ferromagnetic film 215 should have a thickness not smaller than 2 nm in order to have its magnetic characteristics fully developed and analogous to those of the macroscopic material; it should also preferably have a thickness not larger than 100 nm so that it possesses a reduced electrical resistance. The separation between the conducting lines 210 and their cross section should be adjusted so that each one of them can carry the electrical current necessary to create a uniform magnetic field parallel to the ferromagnetic layer 215 and strong enough so as to be able to orient the magnetization of this layer in the desired direction parallel to the film plane. The current and the intensity of the magnetic field required for this operation should be adjusted as a function of the magnetic properties of the ferromagnetic film 215, and in particular depending on the value of its coercive field H_{c}. On top of this ferromagnetic film 215 a layer of molecules with chiral symmetry 220 is deposited by methods such as evaporation in vacuum, or in liquid solution, or by any other suitable method. As described above with reference to FIG. 1, the device also comprises a metallic layer 230 and the chiral molecules are preferably embedded in an insulating protecting layer 225. The device under operation is connected via contacts 240 to a power supply 235.

The principle of operation of this device 200 is schematically depicted in FIG. 4b. By passing an electrical current of the appropriate magnitude and a polarity that is referred to as positive through the conducting wires 210 a magnetic field is created that orients the spins of the conduction electrons in the ferromagnetic layer 215 in one particular direction parallel to the film plane. Then, when a difference of electrical potential is established between the ferromagnetic film 215 and the metallic film 230 by connecting to them a power supply 235 by means of the electrical connections 240, a current of electrons with their spins preferentially aligned parallel to the magnetization of the ferromagnetic layer 215 will circulate across the molecular layer 220. Since this molecular layer is composed of enantiomers that allow the passage of electrons with this component of spin, the current will be easily transmitted and will reach the electrode 230. This configuration will be referred to as closed circuit.

Alternatively, if the electrical current is injected into the conducting wires 210 with the opposite polarity , (negative), as schematically shown in FIG. 4c, then the magnetic field generated will also have the opposite orientation parallel to the ferromagnetic film 215 and it will force the electron spins within this latter to align themselves along this direction. Then, when the voltage difference created by power supply 235 is established between the ferromagnetic film 215 and the metallic electrode 230, the electrons trying to cross the chiral molecular layer 220 will experience a high resistance. This configuration is referred to as open circuit.

Thus, this device 200 operates as a switch for the electrical current that circulates along the conductors 240; the state of this switch is controlled by the other current circulating along the conducting wires 210.

The structural arrangement properties of the chiral layer 110 are experimentally investigated with different techniques. The first technique employed is low-energy electron diffraction (LEED).

This is a standard technique, available in most surface science setups. FIG. 5 shows two electron diffraction patterns, the first one (FIG. 5a) for the bare surface of the Co film, the conducting substrate 105, and the second (FIG. 5b) corresponding to the same sample after the adsorption of the chiral layer 110. The LEED patterns are measured at 300 K with a primary beam energy of 133 eV. The former displays sharp diffraction spots with low background, indicative of good crystalline order with a low number of structural defects in the Co film epitaxially grown on Cu(100). On the contrary, the pattern presented in FIG. 5b shows faint diffracted spots corresponding to the Co underlayer and a strong background with no new spots, implying that the chiral layer 110 does not possess long range order within the surface plane. Commercial LEED systems have a typical coherence length (i. e., the size of the area over which the instrument is capable of detecting correlations among the positions of the scattering objects probed on the surface) of ca. 100 Å; thus, based on the absence of diffracted beams from the molecular overlayer one can estimate that the size of the possible ordered domains cannot be larger than approx. 40-50 Å.

Further structural information can be derived from the angular dependence of the intensity measured in x ray absorption spectroscopy (XAS) experiments. This technique is based on the excitation of inner (core) electrons from specific atoms to empty states above the Fermi level. In the experiments reported here the energy of the x ray photons has been tuned to the binding energy of the carbon is levels. Since these initial state orbitals have spherical symmetry, the angular dependence of the electronic transition probability originates from the relative alignment of the electric field of the exciting radiation and the symmetry of the final states to which the excited electrons are promoted.

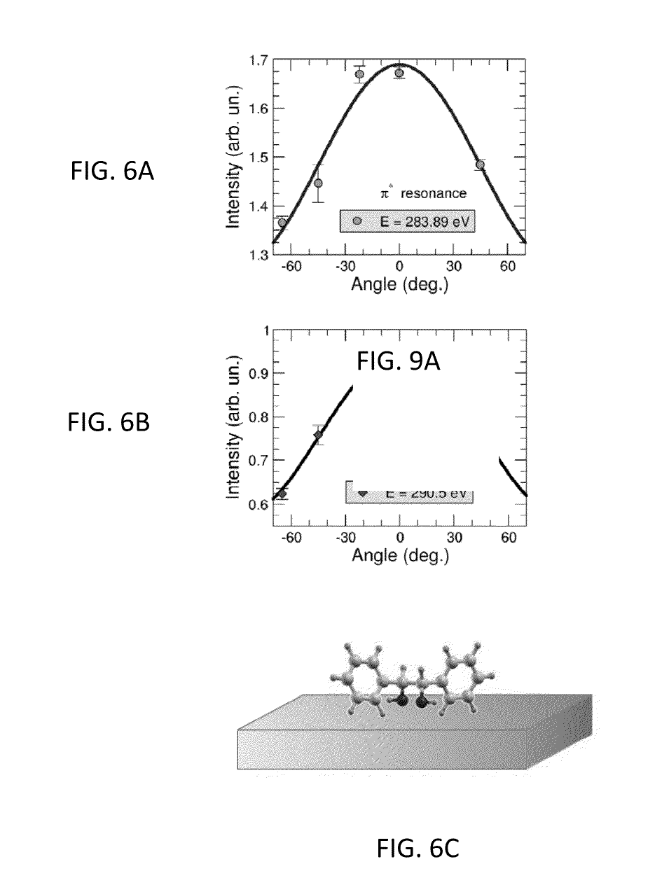

FIGS. 6a-b and 7a-b illustrate the x ray absorption intensities measured at the C K-edge as a function of incidence angle using linearly polarized radiation. These experiments probe the relative alignment of specifically chosen molecular orbitals with respect to the electric field of the x ray beam, which is parallel to the plane of the synchrotron ring. In the graphs of FIGS. 6a-b and 7a-b, zero degrees corresponds to normal incidence: the absorption signal corresponding to the π* molecular orbitals, which are mostly perpendicular to the phenyl rings of the DPED molecule, and the σ* orbitals that constitute mainly the C—C bonds and thus run parallel to the roughly planar structure of the molecules, are monitored.

FIG. 6a-b displays the angular dependence of the XAS intensity for two different electron transitions, measured on a sample consisting of an adsorbed layer of (S,S)-DPED on Co/Cu(100). The curve in FIG. 6a displays the transition probability into a π* final state; the wavefunction for this orbital is roughly perpendicular to the phenyl rings of the DPED molecule. The data in FIG. 6b correspond to transitions into σ* orbitals, which constitute the majority of the C—C bonds and are therefore aligned mostly parallel to the molecular backbone. Both sets of data have maximum intensity when the x ray beam incides perpendicular to the surface (0 degrees with respect to the surface normal in the graph). Since the photon electric field is perpendicular to the beam propagation direction, those two conditions can be met if the (S,S)-DPED molecules are adsorbed parallel to the Co surface and with both phenyl rings in an upright position, as schematically depicted in FIG. 6c.

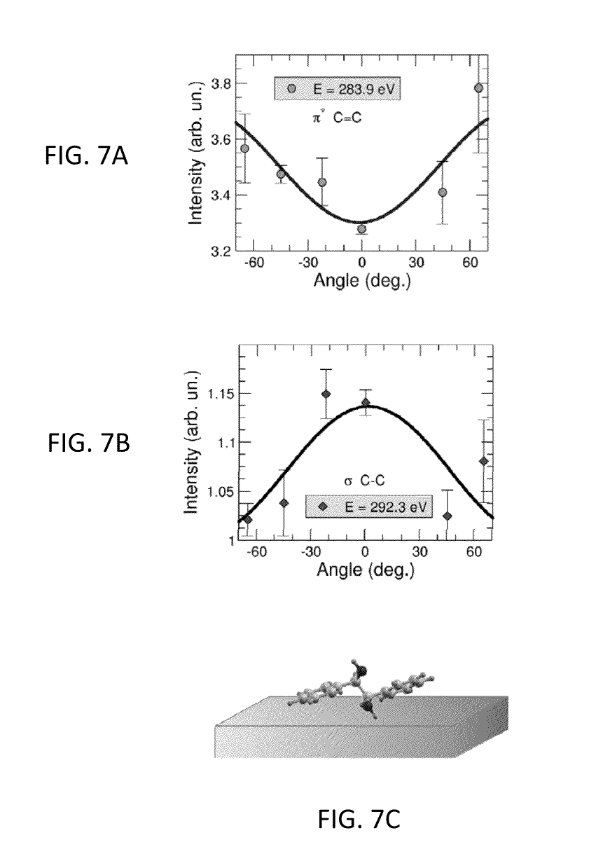

FIG. 7 illustrates the same kind of measurement as described with reference to FIG. 6 but for a (R,R)-DPED film adsorbed on Co/Cu(100), with transitions into the π* orbitals (a) and into σ* orbitals (b). This other chiral enantiomer, (R,R)-DPED, behaves differently to the previous one, (S,S)-DPED. As shown in FIG. 7a, the probability of the transitions into the π* orbitals (perpendicular to the rings) is maximum when the x ray beam incides onto the surface at a grazing incidence, implying that the phenyl rings of these molecules must be oriented approximately parallel to the surface as schematically shown in FIG. 7c. The σ* orbitals for this enantiomer, displayed in FIG. 7b, show a similar behavior as for the other one, which means that the molecules are also lying parallel to the surface in this case.

Experiments carried out at the I3 beamline of synchrotron MAXlab have revealed that electrons crossing a layer of chiral molecules acquire a spin polarization that is determined by the particular chiral symmetry of these latter. In these measurements the 1,2-diphenyl-1,2-ethanediol (DPED) molecule displayed in FIG. 2 has been employed. The experiments also demonstrate that the substitution of one chiral molecule by its mirror image does not simply revert the sign of the spin polarization of the electrons transmitted through the chiral layer, but rather it can change the direction along which the spins become polarized.

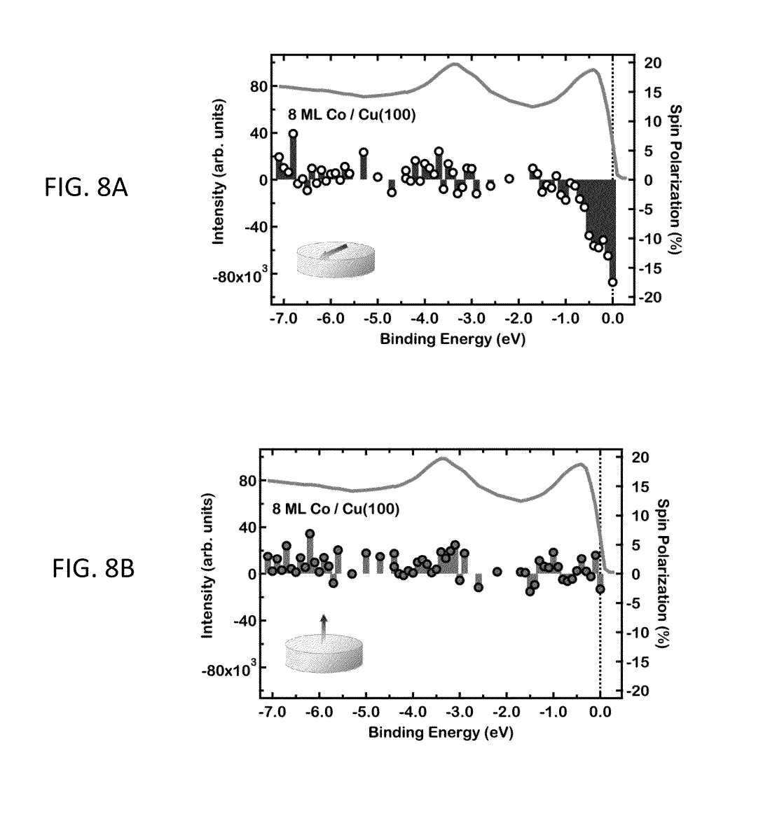

The chiral DPED layers were adsorbed on a substrate consisting of a thin (8 ML thick) film of Co previously deposited on a Cu single-crystal with (001) orientation. Co is a ferromagnetic element which means that it also presents a spontaneous spin polarization of its electrons close to the Fermi level. This characteristic is confirmed by the data presented in FIG. 8a-b. In these measurements the spin analysis is performed along two different directions in space, namely the perpendicular to the sample surface and one axis contained within the surface plane. The data depicted in FIG. 8a clearly show the in-plane spin polarization of the electrons originating from the Co d-band, reaching values of up to nearly 20% right below the Fermi level and decreasing with increasing binding energy; the out-of-plane polarization of these same electrons, presented in FIG. 8b, is negligible.

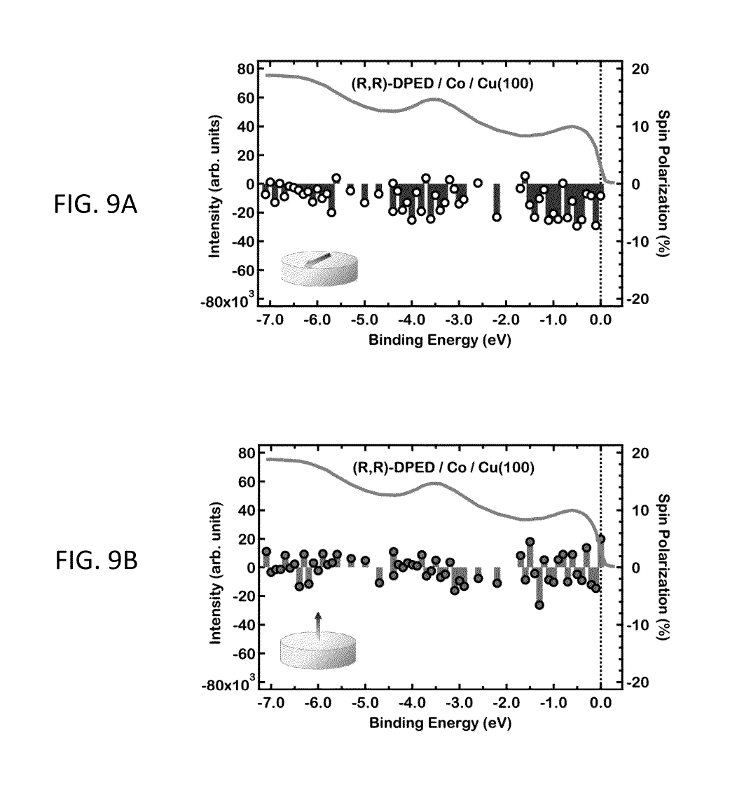

In order to test the effect of the chiral molecules on the spin polarization a very thin (one single molecule) layer of (R,R)-(+)-DPED was adsorbed on a Co/Cu(001) substrate analogous to above, and a similar spin analysis was performed. The results of these measurements are presented in FIG. 9a-b and demonstrate that the electrons emitted from this sample present a roughly constant and homogeneous spin polarization parallel to the surface plane for all the energies investigated—see FIG. 9a—while no significant polarization can be detected along the normal to the surface—FIG. 9b. The spin polarization of the underlying Co electrons is maintained, although embedded now within the uniform signal produced by the molecular layer.

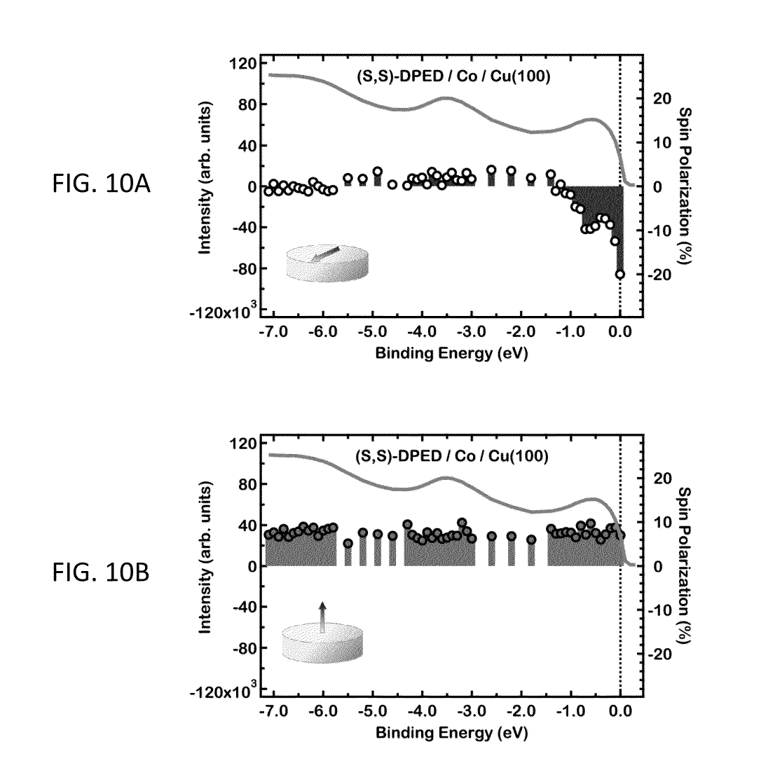

If the (S,S)-(−)-DPED enantiomer is used instead of its mirror image, a similar experiment yields the results depicted in FIG. 10a-b. In this case the in-plane spin polarization of the Co d-band electrons is maintained unaltered, as shown by the spectrum of FIG. 10a, while a constant spin polarization appears pointing along the surface normal for the whole energy range, FIG. 10b.

It is noteworthy that the result of these spin-polarization measurements may be correlated with the two molecular arrangements described above in FIGS. 6c and 7c: the electrons transmitted through (S,S)-DPED films—with the molecules adsorbed in a vertical position—show a polarization perpendicular to the surface whereas the (R,R)-DPED layers, with their rings lying parallel to the surface produce electron currents with in-plane spin polarization. One can thus conclude that the direction of the spin polarization might be indeed related to the spatial orientation of the molecules in the film; nevertheless, a high degree of long range ordering (understood in the sense of translational periodicity) would not be required for that purpose, as demonstrated by the absence of a LEED pattern. The condition to achieve significant spin polarization must be then to produce films in which the molecules show a well-defined orientation, but not necessarily ordered in the periodical sense. Substituting one enantiomer for another does not simply reverse the sign of the spin polarisation, but it can also modify its direction in space, depending on the details of the molecular arrangement on the substrate surface. Hence, the device and method according to the present invention create a possibility to actively control the orientation of the electron spins through the choice of chiral molecules with the appropriate adsorption geometry and orientation on the surface.

According to the present invention the molecules in the chiral layer 110 are intrinsically chiral but they do not have a helicoidal configuration. It can be described as each building block in the chiral layer 110 is intrinsically chiral.

1. Spin filter device comprising a first conducting layer forming a first electrode and a second conducting layer forming a second electrode, and a chiral layer arranged between the first and second electrodes, wherein the chiral layer comprises at least one type of chiral molecules that is intrinsically chiral and the chiral molecules are disorderly distributed on the first conducting layer with a predefined preferential orientation and without long-range periodicity.

2. The spin filter device according to claim 1, wherein the chiral layer further comprises an insulating material forming an insulating protecting layer.

3. The spin filter device according to claim 2, wherein the insulating material is formed of a metal oxide such as Al₂O₃, MgO or SiO₂.

4. The spin filter device according to claim 1, wherein the chiral layer comprises a nanoparticle layer of disordered close packed metallic nanoparticles and the chiral molecules are chemisorbed on the nano particles.

5. The spin filter device according to claim 1, wherein the chiral layer comprises 1,2-diphenyl-1,2-ethanediol.

6. The spin filter device according to claim 1, wherein the chiral layer comprises chiral molecules of different enantiomers.

7. The spin filter device according to claim 6, wherein the use of different enantiomers is utilized to control the direction of the spin polarisation of electrons excited by means of incoming radition.

8. An electron spin switch device comprising an insulating substrate embedding a series of parallel conducting lines, a ferromagnetic film arranged on top of the insulating layer, a chiral layer comprising chiral molecules arranged on top of the ferromagnetic film and a metallic layer arranged on the chiral layer.
